(19) United States
(12) Patent Application Publication
(10) Pub. No.: US 2026/0255088 A1
(43) Pub. Date: Aug. 27, 2026

(54) SET OF PROFILES AND CABINET TO HOUSE EQUIPMENT COMPRISING AT LEAST ONE SET OF PROFILES

(71) Applicant: NILKO TECNOLOGIA LTDA, Pinhais (BR)

(72) Inventor: Andrea Huscher, Pinhais (BR)

(21) Appl. No.: 19/311,294

(22) Filed: Aug. 27, 2025

Related U.S. Application Data
(60) Provisional application No. 63/761,426, filed on Feb. 21, 2025.

(51) Int. Cl. H04Q 1/02; A47B 96/14; H05K 7/18

(52) U.S. Cl. CPC H04Q 1/025; A47B 96/1416; A47B 96/1466; H05K 7/186

(57) ABSTRACT

The present invention relates to a set of profiles comprising at least one column profile and at least one base profile; wherein the column profile comprises a first column profile cavity, a second column profile cavity, a third column profile cavity; and wherein the base profile comprises a first base profile cavity and a second base profile cavity. The present invention also relates to a cabinet to house equipment comprising at least one set of profiles, at least one base region, a plurality of side regions, a rear region, at least one roof and at least one sealing.

### TECHNICAL FIELD

The present invention pertains to the field of electricity, more specifically to frameworks, frames, panels, tables, shelves, casings; details of substations or switching arrangements; frames, panels, tables; parts or accessories thereof.

### INTRODUCTION

The present invention relates to a cabinet, more specifically to a cabinet to house telecommunications and/or energy and/or computer equipment and/or equipment in general, comprising several structural, sealing, opening and closing components.

### BACKGROUND

Cabinets to house equipment, constructed from bent or profiled sheet structures and assembled using welding methods, are widely used due to their initial robustness and the ability to be manufactured in a wide variety of sizes and configurations. In this method, metal sheets, usually steel or aluminum, are cut, bent or profiled to form the structural components, which are then joined by welding to ensure the rigidity of the set. After assembly, these structures typically receive an additional finish, such as painting or galvanization, for corrosion protection and improved aesthetics.

Despite its popularity, this technique presents several challenges and limitations. One of the main problems is related to the deformations that can occur during the welding process due to the heat generated. These deformations can compromise the alignment of parts and require rework, increasing the manufacturing cost and time. Furthermore, although initially strong, welded joints are often the most vulnerable points in the structure, especially under conditions involving vibration, repetitive loads or exposure to harsh environments. These welded areas are more susceptible to cracks and corrosion, which can significantly reduce the durability of the cabinet and compromise the operation and safety of the equipment it houses.

Another common problem is the high weight of structures constructed from bent or profiled sheets, which complicates both transportation and installation, as well as limiting portability and ease of handling. In terms of flexibility, welded cabinets also present disadvantages, since subsequent modifications, expansions or repairs are complicated, often requiring cutting and rewelding, which increases costs and the time needed for adjustments.

Additionally, the manufacturing process of welded cabinets requires skilled operators and strict quality control, which can increase manufacturing costs, especially in large-scale projects. Furthermore, if the weld finishing is not properly executed, rapid oxidation may occur, further reducing the equipment's service life.

These limitations have driven to the search for more modern alternatives, such as modular structures that use interlocking or screw fixing systems, eliminating the need for welding and offering greater flexibility, ease of maintenance and reduced weight. These alternatives also enable more efficient and sustainable manufacturing, with less rework and increased durability in harsh environments.

### Prior art

Known prior art solutions for cabinets to house equipment of the type addressed herein can be found in prior art documents such as the Brazilian document MU8400198, entitled “aperfeiçoamentos introduzidos em armário para abrigo de equipamentos de telecomunicações”, which, according to its main claim, refers to a cabinet to house telecommunications equipment, comprising a sheet/sheet sandwich-type closure system; a constructive arrangement introduced into the frame profiles; a set of electromagnetic sealing and shielding; a constructive arrangement introduced into the hinges; a constructive arrangement introduced into the external sheet closures; a constructive arrangement introduced into the sheet structuring; a constructive arrangement introduced into the sheet composition; a constructive arrangement in the base profiles; latches with tongues; locking mechanisms for door rods; a connection between cabinets; incorporating a generally rectangular insulating blanket, arranged symmetrically and parallel under and along the entire length of the internal face of the external sheet of the top panel, the blanket being formed by a film or layer of aluminum or similar material and arranged under the internal face of the external sheet of the to panel and a foam layer of polyethylene or similar material arranged under the film; and a constructive arrangement introduced into the composition of the sheets formed by an insulating sheet of generally parallelepiped shape, made of thermal insulation materials such as insulating blanket, polystyrene, expanded polyurethane, rock wool or similar and arranged symmetrically fitted along the entire length of the internal part of the sandwich sheets.

Although document MU8400198 presents a cabinet to house telecommunications equipment, it does not present a structure capable of accommodating single-or double-wall closures, with external and internal walls defined by sheets directly fitted and fixed into the structural profiles (column profile and base profile), without the need for auxiliary profiles to frame the closures. In contrast to the solution proposed by MU8400198, the bends of the sheets in the present invention allow for the precise fitting of the closure sheets into the structural profiles, with sealing achieved through application of PU between the sheet and the structure, ensuring the watertightness of the set. Furthermore, the use of auxiliary components herein, such as small fixing corner brackets, which are typically used along the extension/rail of the profiles to ensure the fixing of the internal sheet to the structural set, is not required, resulting in a reduction in assembly components, optimizing the manufacturing process and lowering product costs.

It is also worth mentioning that several prior art solutions can be found in other patent documents such as MU8601692 and U.S. Pat. No. 8,403,431B2. These documents also present disadvantages related to construction and assembly complexity, in addition to the shortcomings already described for the aforementioned document.

The prior art does not provide simple and lower-cost solutions that maintain the technical specifications of the product (rigidity, structural stability, watertightness, chemical behavior, thermal behavior), for a cabinet to house equipment of the type discussed herein.

There is, therefore, room for a cabinet to house equipment that:
a) is produced in a modular manner, while maintaining product performance in terms of its technical specifications (rigidity, structural stability, watertightness, chemical behavior, thermal behavior), considering the use of a reduced amount of material for manufacturing the structure/frame of the cabinet;
b) allows the use of thinner sheet metal without compromising the required characteristics of the product;
c) allows the empty spaces between the closure sheets to promote better internal temperature control within the cabinet;
d) allows optimization of the cabinet manufacturing process, reducing manufacturing time and costs;
e) ensures a high-quality product, lower cost, reduced raw materials consumption, decreased use of construction material (aluminum profile) and with high robustness for the intended application;
f) allows each cabinet configuration to be customized to fit the final project, including dimensional changes, material used and internal equipment;
g) ensures greater agility in the manufacturing process due to its modularity; and
h) eliminates the need for auxiliary components, such as small fixing corner brackets typically used along the extension/rail of the profiles to ensure the fixing of the internal sheet to the structural set.

### OBJECTS OF THE INVENTION

The object of the invention is, therefore, to provide a cabinet to house telecommunications equipment, according to the characteristics of claim 1 of the appended set of claims.

Additional characteristics and details thereof are presented in the dependent claims.

### DESCRIPTION OF THE DRAWINGS

For a better understanding and visualization of the object to which the invention relates, it will now be described with reference to the accompanying figures, representing the obtained technical effect by means of an exemplary embodiment without limiting the scope of the present invention, wherein, schematically:

FIG. 1: shows an exploded perspective view of a cabinet to house equipment according to the invention;

FIG. 2: shows a perspective view of the modular structure with the column and base profiles and corner brackets of a cabinet to house equipment according to the invention;

FIG. 3: shows an enlarged perspective view of the upper part of the modular structure with the column and base profiles and corner brackets of the cabinet in FIG. 2;

FIG. 4: shows the upper sectional view of a column profile geometry of a cabinet to house equipment according to the invention;

FIG. 5: shows the top view of a base profile geometry of a cabinet to house equipment according to the invention;

FIG. 6: shows a perspective view of the base, the internal and external sheet of the side closure of a cabinet to house equipment according to the invention;

FIG. 7: shows an enlarged view of detail A in FIG. 6, showing a right side closure of the base profile that connects the internal and external sheets of the side closure;

FIG. 8: shows an upper view of a cabinet to house equipment according to the invention;

FIG. 9: shows an enlarged view of detail B of FIG. 8, showing the fitting of the external side fixed closure, wherein the column profile connects the rear closure internal sheet with the side closure internal sheet and the side closure external sheet, using the bent sheet reinforcement;

FIG. 10: shows an upper view of a cabinet to house equipment according to the invention;

FIG. 11: shows an enlarged view of detail C in FIG. 10, showing an internal fixed closure, wherein the column profile connects the rear closure internal sheet and the side closure internal sheet;

FIG. 12: shows an upper view of a cabinet to house equipment according to the invention;

FIG. 13: shows an enlarged view of detail D of FIG. 12, showing the fitting of the external rear fixed closure, wherein the column profile connects the rear closure internal sheet, the rear closure external sheet, using the structural reinforcement riveted to the external fixed closure, with the side closure internal sheet, using the bent sheet reinforcement;

FIG. 14: shows a perspective view of the cabinet to house equipment showing the side internal and external closures according to the invention;

FIG. 15: shows a front view of the cabinet to house equipment, according to the invention;

FIG. 16: shows an upper view of the cabinet to house equipment according to the invention;

FIG. 17: shows an enlarged view of detail E of FIG. 16, showing the fitting of the side closures, wherein the column profile connects the side closure internal sheet with the side closure external sheet, using the bent sheet reinforcement;

FIG. 18: shows a side perspective view of the cabinet to house equipment, highlighting the region where the sealing is applied to the side and rear closure internal sheets, according to the invention;

FIG. 19: shows a perspective view of the cabinet to house equipment, highlighting the side and rear regions wherein the sealing is applied to the side closure internal sheets according to the invention;

FIG. 20: shows an enlarged perspective view of the cabinet to house equipment, highlighting the upper right corner of the side closure internal sheet where the sealing is applied to the side closure internal sheets, according to the invention;

FIG. 21: shows a perspective view of the door of the cabinet to house equipment, highlighting the hinges and the latch according to the invention; and

FIG. 22: shows an enlarged perspective view of the cabinet to house equipment, highlighting the assembly of the base profile with the side closure internal sheet, the side closure external sheet and the sheet clamp, according to the invention.

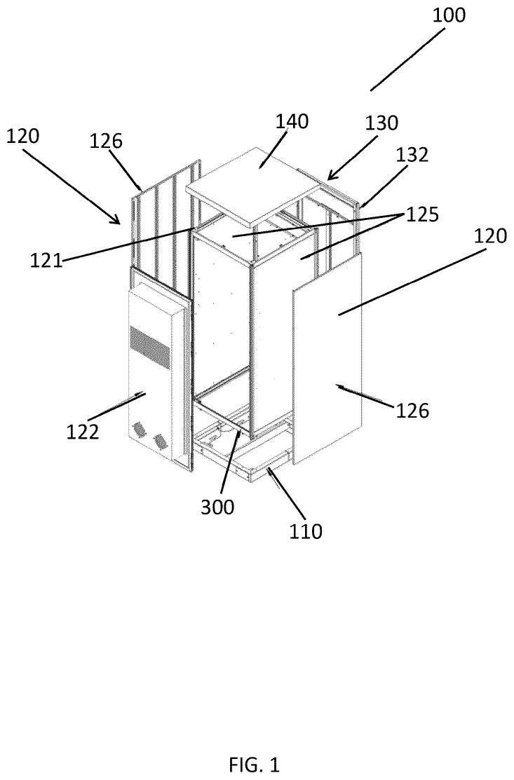

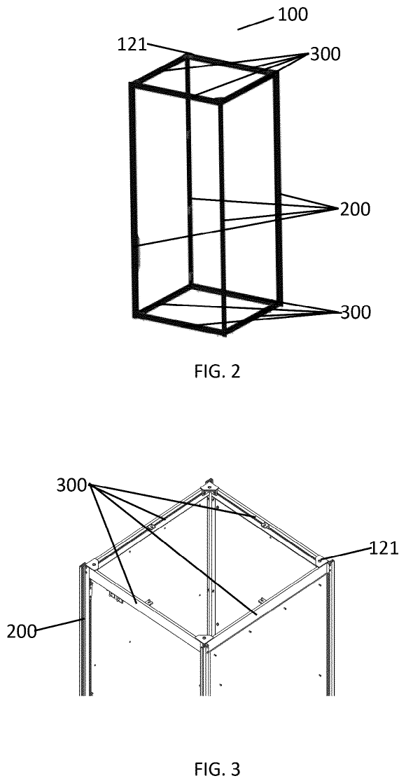

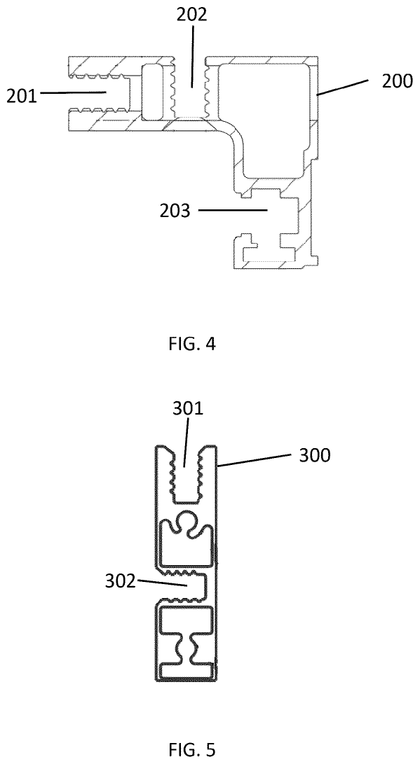

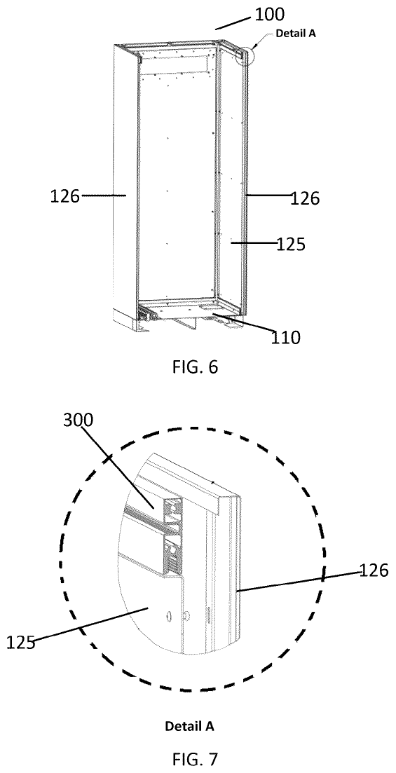

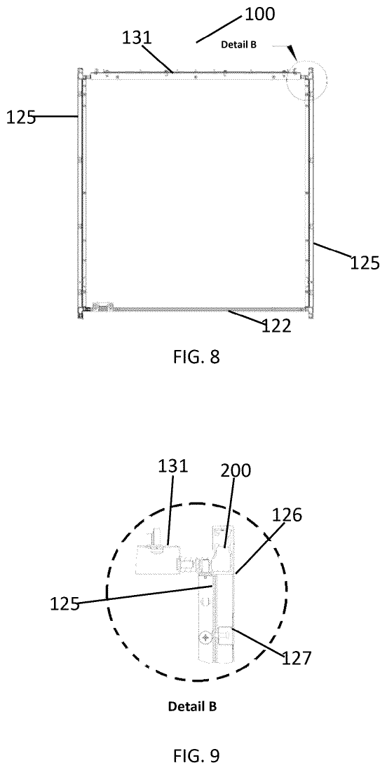

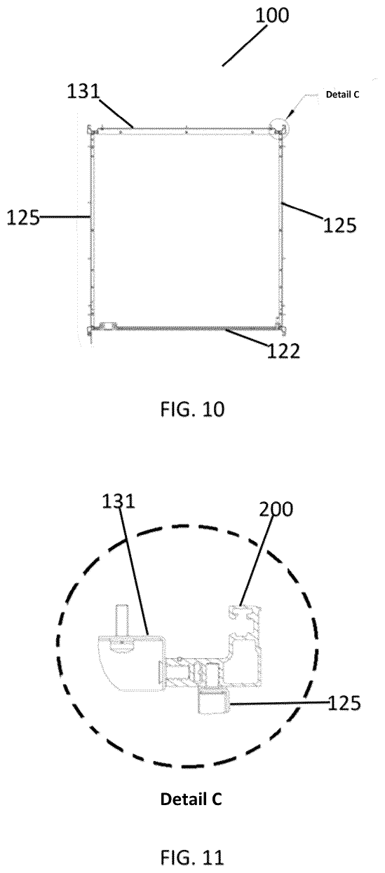

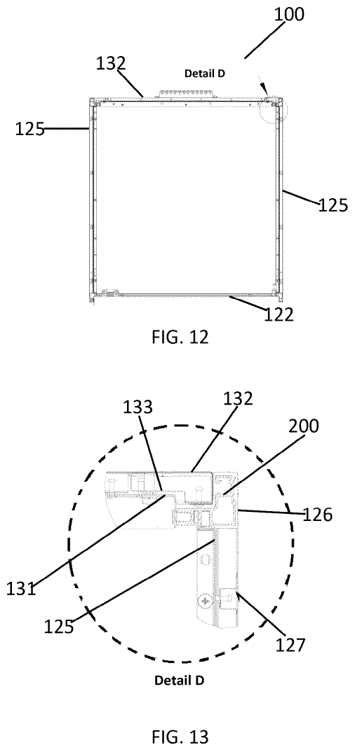

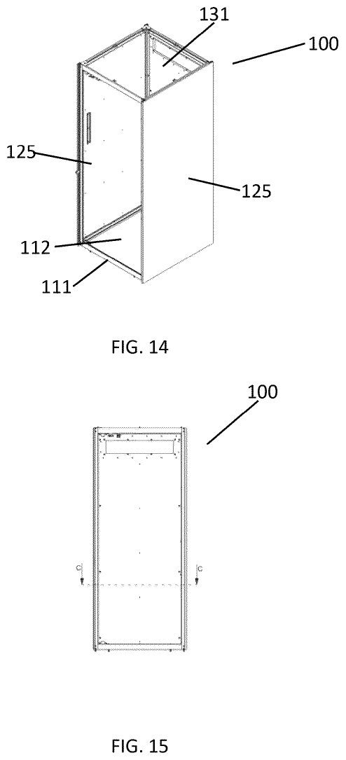

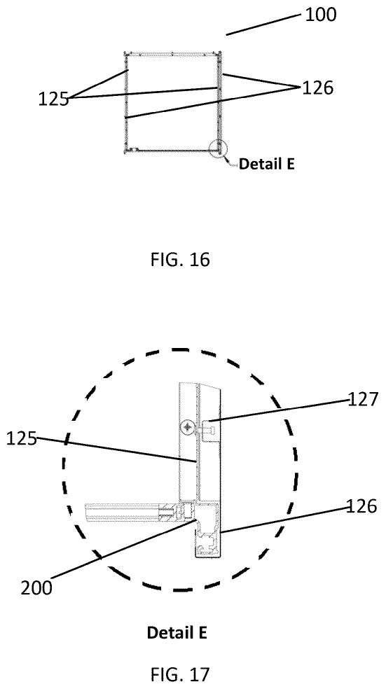

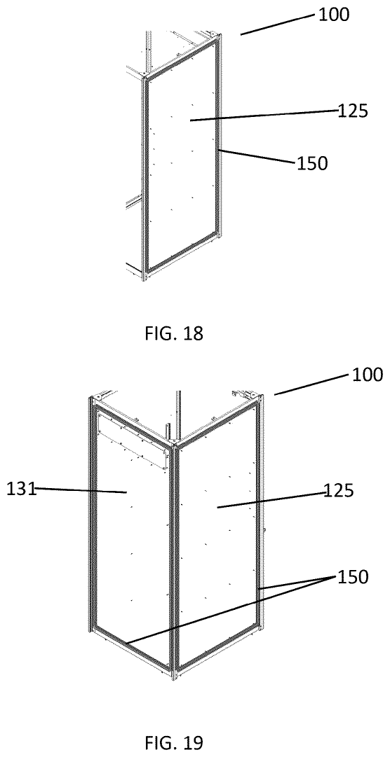

### DETAILED DESCRIPTION OF ONE OR MORE EMBODIMENTS OF THE INVENTION

The following detailed description refers to the appended drawings wherein, by way of non-limiting illustration, embodiments of the present invention are shown. These embodiments are described so as to allow a person skilled in the art to reproduce the results. Other embodiments resulting from structural, mechanical, logical, electric, and electronic changes are possible and can be performed without departing from the spirit and scope of the present invention. The following detailed description should therefore not be understood in a restrictive or limiting manner.

A set of profiles, according to the present invention, is responsible for allowing the assembly and fixing of the components of a cabinet to house equipment (100).

The set of profiles comprises at least one column profile (200) and at least one base profile (300).

The column profile (200) is responsible for supporting the vertical structure of the cabinet to house equipment (100), providing mechanical resistance and fixing points for internal components, such as trays, rails and equipment.

The column profile (200) comprises a first column profile cavity (201), a second column profile cavity (202) and a third column profile cavity (203).

The base profile (300) serves as support for the entire structure of the cabinet to house equipment (100), evenly distributing the weight and ensuring fixing to the floor or installation site.

Furthermore, the base profile (300) contributes to insulation and protection against humidity, vibrations and other external agents, providing a stable base for the installation and safe operation of telecommunication equipments.

The base profile (300) comprises a first base profile cavity (301) and a second base profile cavity (302).

Preferably, the column (200) and base (300) profiles are made of metallic material. In a non-limiting manner, the column (200) and base (300) profiles are manufactured from aluminum, copper, brass, bronze, carbon steel, magnesium, nickel, among others.

The cabinet to house equipment (100), also commonly known as a cabin, casing, housing or rack, is a structure designed to protect devices and systems related to telecommunications and/or energy and/or computer equipment and/or equipment in general, ensuring the safety, organization and ideal functioning of said equipment.

The cabinet to house equipment (100) comprises at least one base region (110), a plurality of side regions (120), a rear region (130), at least one roof (140) and at least one sealing (150).

Preferably, the cabinet to house equipment (100) is made of metal material. In a non-limiting manner, the cabinet to house equipment (100) is produced from aluminum, copper, brass, bronze, carbon steel, magnesium, nickel, among others.

The base region (110) of the cabinet to house equipment (100) provides support for the entire structure of the cabinet to house equipment (100) and the internal equipment, raising the cabinet above ground level, protecting it against humidity, flooding, dust and other external elements that may compromise the operation of the devices installed internally to the cabinet to house equipment (100).

The base region (110) comprises at least one sheet clamp (111) and one sill internal sheet (112).

The sheet metal clamp (111) is an element installed in the second base profile cavity (302) responsible for fixing the roof internal sheet (141).

The side regions (120) are regions located on the sides of the cabinet to house equipment (100) and comprise a plurality of corner brackets (121), at least one door (122), at least one hinge (123), at least one latch (124), a plurality of side closure internal sheets (125), a plurality of side closure external sheets (126) and at least one bent sheet reinforcement (127).

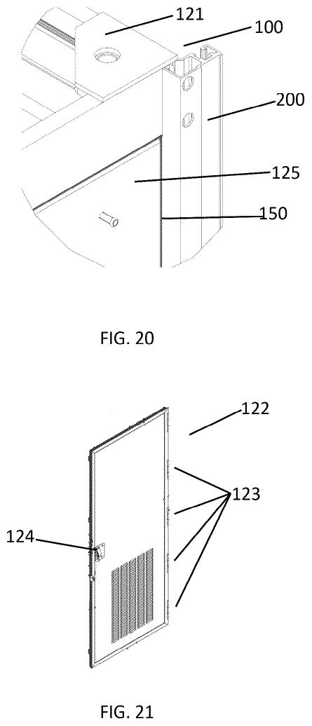

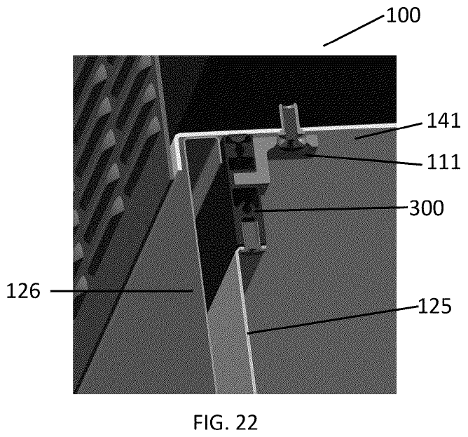

The corner brackets (121) are installed at the ends of the cabinet to house equipment (100), as shown in FIGS. 3 and 20. The corner brackets (121) increase the rigidity of the cabinet structure, ensuring that it remains stable and resistant even under harsh conditions such as vibrations or impacts.

The door (122) has a double wall made of metal material and is prepared to receive thermal dissipation equipment, such as heat exchangers and air conditioning, fans and filters. In addition, the door (122) may include openings or ventilation systems, such as grilles or outlets, which assist in circulating air and dissipating heat produced by the equipment, ensuring the safe and efficient operation of the system.

The hinge (123) is a prior art hinge that aims to fix the door (122) to the cabinet to house equipment (100).

The latch (124) is an element designed to keep the door (122) securely closed, so as to prevent the door (122) from opening accidentally, or anyone from accessing the inside of the cabinet to house equipment (100) without authorization.

The side closure internal sheets (125) are metal plates installed on the base profile (300) that aim to form an internal region in the cabinet to house equipment (100).

The side closure external sheets (126) are metal plates installed on the column profile (200) that aim to form an external region in the cabinet to house equipment (100).

The bent sheet reinforcement (127) is an element responsible for fixing the side closure external sheets (126) to the side closure internal sheet (125).

Furthermore, the bent sheet reinforcement (127) can also be, without limitation, bounded to the side closure external sheet (126) using adhesive tape, and the bent sheet reinforcement (127) can serve as a connection point between the side closure internal sheet (125) and the side closure external sheet (126).

The rear region (130) is a region located at the rear part of the cabinet to house equipment (100) and comprises at least one rear closure internal sheet (131), at least one rear closure external sheet (132) and at least one structural reinforcement riveted to the external fixed closure (133).

The rear closure internal sheet (131) is a metal plate installed on the column profile (200) and on the base profile (300), which aims to form an internal region in the cabinet to house equipment (100).

The rear closure external sheet (132) is installed in such a way as to be fixed to the rear closure internal sheet (131) through reinforcements.

It should be noted that the sheets (125, 126, 131, 132) can be manufactured in metallic material, preferably aluminum. Furthermore, the empty spaces formed between the sheets (125, 126, 131, 132) promote better internal temperature control.

The structural reinforcement riveted to the external fixed closure (133) is an element responsible for fixing the rear closure internal sheet (131) and the rear closure external sheet (132)

The roof (140) protects the internal devices against external agents, such as rain, dust, solar radiation and other climatic elements. The roof (140) also contributes to thermal insulation, helping to reduce the impact of heat generated by exposure to the sun, which is essential for maintaining the internal temperature at adequate levels.

In addition, the roof (140) may include openings or ventilation systems, such as grilles or exhaust outlets, which assist in the circulation of air and the dissipation of heat produced by the equipment, ensuring the safe and efficient operation of the system. The roof (140) is made of metal material, preferably aluminum.

The roof (140) comprises an internal roof sheet (141) and may comprise a top panel preferably made of metal material which acts as the first barrier against the weather, protecting the cabinet against rain, snow, dust, sunlight and other weather elements. The internal roof top panel complements this protection, functioning as an additional layer that reinforces thermal insulation and protects equipment against sudden temperature changes. This double layer also contributes to the dissipation of internally generated heat and reduces the transfer of external heat, ensuring a controlled and safe environment for telecommunications devices.

The sealing (150) of the side (125) and rear (131) closure internal sheets of the cabinet to house equipment (100) can be made, without limitation, of expanded polyurethane (PU) material.

The sealing (150) has the main function of ensuring protection against the entry of water, dust and other external agents that could compromise the functioning of the internal equipment. The sealing (150) acts as an efficient insulator, filling possible irregularities and creating an airtight barrier that improves the watertightness of the cabinet to house equipment (100).

Furthermore, the sealing (150) helps to minimize heat exchange and temperature variation inside the cabinet to house equipment (100), contributing to thermal stability.

The set of profiles is installed in the cabinet to house equipment (100) so that:
the column profile (200) cooperates with the rear closure internal sheet (131) through the first column profile cavity (201) and fixing elements inserted into the first column profile cavity (201) can be used to fix the rear closure internal sheet (131) to the column profile (200), such as, but not limited to, rivets, screws, clamps, fixing elements, connectors, fasteners, fixing pins or mechanical clips;
the column profile (200) cooperates with the side closure internal sheet (125) through the second column profile cavity (202) and fixing elements inserted into the second column profile cavity (202) can be used to fix the side closure internal sheet (125) to the column profile (200), such as, but not limited to, rivets, screws, clamps, fixing elements, connectors, fasteners, fixing pins or mechanical clips;
the structural reinforcement riveted to the external fixed closure (133) connects the rear closure internal sheet (131) and the rear closure external sheet (132), so as to not require any fixing means between the rear closure external sheet (132) and the column profile (200);
the rear closure internal sheet (131) cooperates simultaneously with the first column profile cavity (201) and with the first base profile cavity (301);
the column profile (200) cooperates with the side closure external sheet (126) and with the bent sheet reinforcement (127), where the side closure external sheet (126) surrounds the third column profile cavity (203), and fixing elements inserted into the bent sheet reinforcement (127) can be used to fix the side closure external sheet (126) to the side closure internal sheet (125), such as, but not limited to, rivets, screws, clamps, fixing elements, connectors, fasteners, fixing pins or mechanical clips;
the base profile (300) cooperates with the side closure internal sheet (125) through the first base profile cavity (301) and fixing elements inserted in the first base profile cavity (301) can be used to fix the side closure internal sheet (125) to the base profile (300), such as, without limitation, rivets, screws, clamps, fixing elements, connectors, fasteners, fixing pins or mechanical clips; and
the base profile (300) cooperates simultaneously with the side closure internal sheet (125) and with the sheet clamp (111) through the second base profile cavity (302), where the end of the sheet clamp (111) is inserted into the second base profile cavity (302) and where fastening elements inserted into the sheet clamp (111) cavity can be used to fix the roof internal sheet (141) or the sill internal sheet (112) to the sheet clamp (111), such as, without limitation, rivets, screws, clamps, fixing elements, connectors, fasteners, fixing pins or mechanical clips.

It should be noted that the cabinet to house equipment (100) must be designed to meet the specific needs of the environment and conditions wherein it will be used. Thus, it is possible to have variations in the quantity and arrangement of its elements without departing from the scope of protection claimed herein.

### Conclusion

It will be easily understood by one skilled in the art that modifications may be performed herein without departing from the concepts set out in the description above. Such modifications should be considered as included within the scope of the present invention. Consequently, the particular embodiments previously described in detail are illustrative and exemplary only and are non-restrictive as to the scope of the present invention, which should be given the full extent of the appended claims and any and all equivalents thereof.

1. A set of profiles, comprising:
at least one column profile; and
at least one base profile;
wherein the column profile comprises a first column profile cavity, a second column profile cavity, and a third column profile cavity; and
wherein the base profile comprises a first base profile cavity and a second base profile cavity.

2. The set of profiles according to claim 1, wherein the first column profile cavity is configured to cooperate with a rear closure internal sheet; and
wherein fixing elements are inserted into the first column profile cavity to fix the rear closure internal sheet to the column profile.

3. The set of profiles according to claim 1, wherein the second column profile cavity is configured to cooperate with a side closure internal sheet; and
wherein fixing elements are inserted into the second column profile cavity to fix the side closure internal sheet to the column profile.

4. The set of profiles according to claim 1, further comprising a structural reinforcement riveted to an external fixed closure to fix and connect the rear closure internal sheet and a rear closure external sheet.

5. The set of profiles according to claim 4, wherein the rear closure internal sheet cooperates simultaneously with the first column profile cavity and with the first base profile cavity.

6. The set of profiles according to claim 1, wherein the column profile is configured to cooperate with a side closure external sheet and with a bent sheet reinforcement, wherein the side closure external sheet surrounds the third column profile cavity; and
wherein fixing elements are inserted into the bent sheet reinforcement to fix the side closure external sheet to the side closure internal sheet.

7. The set of profiles according to claim 1, wherein the first base profile cavity is configured to cooperate with the side closure internal sheet; and
wherein fixing elements are inserted into the first base profile cavity to fix the side closure internal sheet to the base profile.

8. The set of profiles according to claim 1, wherein the second base profile cavity is configured to cooperate simultaneously with a side closure internal sheet and with a sheet clamp, wherein the end of the sheet clamp is inserted into the second base profile cavity; and
wherein fixing elements are inserted into the cavity of the sheet clamp to fix a roof internal sheet or a sill internal sheet to the sheet clamp.

9. A cabinet to house telecommunications equipment, the cabinet comprising:
at least one set of profiles as defined in claim 1, wherein the cabinet to house equipment additionally comprises at least one base region, a plurality of side regions, a rear region, at least one roof, and at least one sealing, wherein the roof comprises a roof internal sheet.

10. The cabinet according to claim 9, wherein the base region comprises at least one sheet clamp and a sill internal sheet;
wherein the side regions comprise a plurality of corner brackets, at least one door, at least one hinge, at least one latch, a plurality of side closure internal sheets, a plurality of side closure external sheets, and at least one bent sheet reinforcement; and
wherein the rear region comprises at least one rear closure internal sheet, at least one rear closure external sheet and at least one structural reinforcement riveted to the external fixed closure.
